(19) United States
(12) Patent Application Publication
(10) Pub. No.: US 2024/0208443 A1
(43) Pub. Date: Jun. 27, 2024

(54) On-Board Power Supply System for a Vehicle

(71) Applicant: Bayerische Motoren Werke Aktiengesellschaft, Muenchen (DE)

(72) Inventors: Florian BIERWIRTH, Steinhoering (DE); Joachim FROESCHL, Herrsching (DE); Juergen GEBERT, Moosburg (DE); Yusuf GROTTENTHALER, Mainburg (DE)

(21) Appl. No.: 18/287,319

(22) PCT Filed: Feb. 28, 2022
(86) PCT No.: PCT/EP2022/054974

§ 371 Date: Oct. 18, 2023

(30) Foreign Application Priority Data
Apr. 19, 2021 (DE) 10 2021 109 796.7

(51) Int. Cl. B60R 16/03; G01R 31/08; G01R 31/52

(52) U.S. Cl. CPC B60R 16/0307; G01R 31/086; G01R 31/52

(57) ABSTRACT

An on-board power supply system for a vehicle includes an electrical power supply path, a first voltage-measuring apparatus at a first end of the power supply path, a second voltage-measuring apparatus at a second end of the power supply path, and an evaluation device which is connected to the voltage-measuring apparatuses and is configured to subject a first voltage curve measured by way of the first voltage-measuring apparatus and a second voltage curve measured by way of the second voltage-measuring apparatus to a cross-correlation, and then, if the result of the cross-correlation meets a predetermined criterion, to determine an anomalous degradation state of the power supply path.

### BACKGROUND AND SUMMARY

The invention relates to an on-board power supply system for a vehicle, having an electric power supply path, a first voltage-measuring device at a first end of the power supply path, a second voltage-measuring device at a second end of the power supply path and an evaluation apparatus that is connected to the voltage-measuring devices and is configured to identify an anomalous degradation state of the power supply path. The invention also relates to a vehicle having such an on-board power supply system. The invention furthermore relates to a method for identifying a degradation state of a power supply path of an on-board power supply system of a vehicle. The invention is particularly advantageously applicable to electric vehicles.

An anomalous degradation, caused for example by frictional effects, etc., may occur along a power supply path of a vehicle, and may impair the electrical conductivity of said power supply path and, in the worst-case scenario, lead to a path breakage. In order to guarantee the availability of a power supply in particular for safety-relevant functional components of the vehicle, these are commonly supplied with power via two redundant power supply paths.

The object of the present invention is to at least partially overcome the disadvantages of the prior art and in particular to provide an improved possibility of ensuring a supply of power to electrically operated functional components of a vehicle.

This object is achieved according to the features of the claimed invention.

The object is achieved by an on-board power supply system for a vehicle,

having an electric power supply path between two functional components of the on-board power supply system, a first voltage-measuring device at a first end of the power supply path, a second voltage-measuring device at a second end of the power supply path and an evaluation apparatus that is connected to the voltage-measuring devices and that is designed to cross-correlate a first voltage profile measured by way of the first voltage-measuring device and a second voltage profile measured by way of the second voltage-measuring device and, when the result of the cross-correlation meets a predefined criterion, to identify an anomalous degradation state of the power supply path.

This on-board power supply system yields the advantage that the cross-correlation makes it possible to identify the healthy state or degradation state of the power supply path in a particularly accurate and reliable manner and may in the process be implemented with low computing outlay. Any worsening of the current-carrying capability caused by anomalous degradation processes may in particular be diagnosed predictively and failure of the power supply path, which could in turn lead to failure of or to malfunctions with functional components of the on-board power supply system, may then be prevented by initiating appropriate countermeasures. Using such a predictive on-board power supply system diagnosis thus makes it possible to increase the availability of functional components and units, thereby opening up an inexpensive alternative or additional safeguarding to the redundant design of power supply paths used at present.

The on-board power supply system may be an on-board power supply system of a vehicle. The on-board power supply system may be a high-voltage on-board supply system, a low-voltage on-board supply system or a combined high-voltage and low-voltage on-board supply system.

The power supply path is intended in particular to channel current or electrical energy to be supplied to at least the on-board power supply system, for example a consumer. A pure data line (for example measurement line, data bus line, etc.) is in particular not considered to be a power supply path.

One development is that the power supply path comprises at least one power supply line, for example a cable, and/or at least one electrical connection system connecting the power supply line. Said connection system is particularly advantageous, since electrical connection systems are particularly susceptible to an anomalous degradation. One development is that the power supply path comprises at least one electrical line path present inside at least one functional component.

The voltage-measuring device is used to determine, in particular measure, a voltage at the respective end of the power supply path.

The evaluation apparatus may be an on-board computer of the vehicle or a dedicated evaluation apparatus connected thereto. The evaluation apparatus is configured, for example programmed, to store voltage measured values measured within a predefined time window, in particular simultaneously, in the form of a profile or curve, and to cross-correlate them. Cross-correlation is well known in principle from the field of signal processing.

One development is that the cross-correlation is a displacement-free discrete cross-correlation over a sequence of M voltage measured values, recorded in pairs at the same times (in the same sampling intervals), of the two voltage profiles. The result of the cross-correlation is in particular a cross-correlation coefficient φ. The cross-correlation coefficient φ is a measure of the match or deviation between the two voltage profiles. The smaller the cross-correlation coefficient φ, the greater the deviation between the voltage profiles. Displacement-free cross-correlation is particularly easy to implement and may be used in practice specifically in the event that the voltage measured values of the two voltage profiles are recorded at the same times. However, a cross-correlation based on voltage profiles recorded with a time shift is also possible in principle, wherein the voltage profiles may then be aligned for example through a time shift.

One example of a formula for the displacement-free discrete determination of the cross-correlation coefficient φ from a set of M synchronously recorded pairs of measured values U₁ and U₂ at M measurement or sampling times is as follows:

$$φ ( {U}_{1} , {U}_{2} ) = \frac{1}{M} \cdot {\sum }_{n = 0}^{M - 1} {U}_{1} [ n ] \cdot {U}_{2} [ n ]$$

wherein U₁[n] is an nth voltage value, measured at the first end of the power supply path, of the sequence of M voltage values of the associated voltage profile and U₂[n], in the same way, is an nth voltage value measured at the second end of the power supply path.

In the present on-board power supply system, use is made of the fact that a voltage drop occurs across the power supply path due to its ohmic resistance, meaning that the two voltage profiles, although they have a highly similar shape, do not have the same voltage level. As the resistance of the power supply path increases, the voltage difference between the two voltage profiles also increases, as a result of which the cross-correlation coefficient φ drops. The increasing resistance may be brought about by anomalous degradation effects, meaning that the cross-correlation coefficient φ represents a measure for identifying the anomalous degradation state.

An anomalous degradation is understood to mean in particular a worsening of the current-carrying capability of the power supply path that is not based on a permissible (normal) degradation brought about by ageing. Such an anomalous degradation typically leads to functional failure of the power supply path noticeably more quickly than (permissible) ageing and also cannot be taken into consideration when designing the on-board power supply system. While for example an anomalous degradation may lead to failure of the power supply path within hours or days, failure due to ageing typically occurs in the range of years, if at all. The anomalous degradation may in principle comprise all phenomena other than normal ageing that manifest themselves in an increase in resistance of the power supply path, for example corrosion processes, wear processes on contacts, frictional corrosion, damage on the power line, relaxation phenomena, arcs, line impairments due to unusually high current loads, cable damage and breakages, loose contacts, etc.

Identifying the anomalous degradation or the anomalous degradation state of the power supply path serves in particular to identify the beginning of an anomalous degradation or an anomalous degradation that is already underway before this results in critical impairment of the current-carrying capability of the power supply path.

When the anomalous degradation state is identified, at least one action may be triggered, for example a message may be output to the user of the vehicle and/or to a point of service (workshop, manufacturer of the vehicle, etc.)

The power supply path may in particular electrically connect two functional components of the on-board power supply system to one another. The functional components of the on-board power supply system may for example comprise at least one energy source (battery, generator, etc.), at least one consumer, at least one power distributor, at least one electronic fuse, etc. The power supply path may thus for example connect an electronic fuse to a consumer. The electronic fuse is used here in particular to protect the power supply path.

One embodiment is that the criterion is that of a cross-correlation coefficient reaching or falling below a predefined threshold value. In other words, the criterion comprises comparing whether the cross-correlation coefficient is equal to or less than the predefined threshold value. This yields the advantage of a particularly simple implementation.

One development is that an anomalous degradation state of the power supply path is first identified when the cross-correlation coefficient φ reaches or falls below the threshold value multiple times within a predefined period. This makes it possible to advantageously rule out only short-term effects that are not based on a degradation and that influence the cross-correlation coefficient φ. Such effects that are not based on a degradation may be brought about for example by problems with a data transmission or a current source. This takes into consideration the fact that a degradation is typically permanent and does not rectify itself, but rather, on the contrary, is often even self-reinforcing.

One embodiment is that the threshold value is a threshold value able to be adapted variably to at least one ambient parameter. This achieves the advantage that ambient effects that influence the cross-correlation coefficient but are not based on an abnormal degradation are also taken into consideration, as a result of which the probability of incorrect identification or false alarms is in turn able to be considerably reduced. The fact that the threshold value is a threshold value that is able to be adapted variably may also be expressed in that the threshold value is a threshold value dependent on at least one ambient parameter.

One development is that the at least one ambient parameter comprises at least one parameter from the group temperature of the power supply path and/or humidity in the region of the power supply path.

Taking into consideration the temperature of the power supply path is particularly advantageous because its ohmic resistance, and therefore also the voltage dropped across it, depends to a noticeable extent on the temperature. This in turn achieves the advantage that the probability of incorrect recognition or lack of recognition of an anomalous degradation is noticeably reduced. The temperature may for example be measured using a temperature sensor, be estimated from a temperature in the engine compartment of the vehicle and/or be estimated from an ambient temperature of the vehicle.

It is also possible to estimate the temperature of the power supply path using a current strength of a current flowing through said power supply path or by observing a current history through the power supply path, for example on the basis of empirical values—stored for example in a table or characteristic curve—or through model-based estimates. The higher the current strength, the higher usually the temperature of the power supply path as well. The threshold value may therefore also be a threshold value dependent on the current strength of the current flowing through the power supply path.

Humidity may likewise influence the ohmic resistance of the power supply path through leakage currents. The higher the humidity, the more the resistance typically drops and the higher the cross-correlation coefficient becomes. The humidity may be for example an air humidity in the environment of the vehicle.

One development is that the threshold value is a threshold value dependent on a (permissible) ageing of the power supply path. This achieves the advantage of being able to distinguish between permissible ageing of the power line and an “abnormal” degradation, for example caused by the occurrence of wear, component defects, installation defects and/or material defects, etc. This is advantageous because the effect of permissible ageing is typically known to a manufacturer of the vehicle and is able to be rectified for example through routine maintenance and therefore generally does not lead to failure of the power supply path while driving. The anomalous degradation is by contrast not able to be predicted when designing the on-board power supply system and is therefore particularly critical because it may lead to an unforeseeable failure of the power supply path. The fact that the threshold value is a threshold value dependent on permissible ageing of the power line may for example be implemented such that it changes, for example decreases, as the age or service life of the vehicle or the power line increases.

One development is that an anomalous degradation state of the power supply path is identified when the profile of the cross-correlation coefficient exhibits a certain behavior, for example a comparatively rapid drop.

One embodiment is that the criterion comprises a deviation of a profile of the cross-correlation coefficient from a reference profile of the cross-correlation coefficient. This advantageously also makes it possible to evaluate temporal changes of the cross-correlation coefficient, as a result of which the identification of an anomalous degradation state becomes even more reliable. The reference profile of the cross-correlation coefficient may thus for example be determined from historical values of the vehicle, defined in the factory, etc. The reference profile used for the cross-correlation may be selected from a group or set of different reference profiles, for example through a best match with reference profiles for: typical driving scenarios (for example city traffic, intercity traffic, etc.), different locations of the vehicle (for example determined automatically using GPS), different temperature values of the power supply path and/or different humidity values in the region of the power supply path, etc. One embodiment is therefore that the reference profile comprises a profile of cross-correlation coefficients that is typical for a journey of the vehicle.

The measure of the deviation between the current profile of the cross-correlation coefficient φ and the reference profile may for example be identified using the least squares method or using a further cross-correlation.

One embodiment is that the voltage profiles are determined in a concomitant time window, in particular having a constant width. This allows particularly reliable identification of the anomalous degradation state. The width of the time window may be for example a predefined period or a number of successive measured values, in particular when the measured values are recorded at constant time intervals. A time window having a constant width comprises an identical number of measured values but is moved along in time, wherein a last-measured measured value is then in particular incorporated into the voltage profile and the oldest measured value from the time window is removed in exchange.

One embodiment is that the power supply path comprises at least one electrical connection system. This is particularly advantageous for plug connections, because plug connections in particular, due to the requirement for a detachable connection, are particularly susceptible to anomalous degradation phenomena such as frictional corrosion, etc. However, the connection system is not restricted thereto, and may for example also be a screwed connection.

One embodiment is that the first end and/or the second end of the power supply path has an electronic fuse into which the voltage-measuring device is integrated. This yields the advantage that the voltage at the electronic fuse (also known as “E-fuse”) is able to be measured without additional measurement outlay, since a voltage-measuring function is already provided by design in electronic fuses.

Also known are electronic fuses that are also configured to measure a current. Using the electronic fuse to measure a current yields the advantage that the current strength of the electric current flowing through the power supply path is thus also known with little outlay, which current may in turn for example be used to adapt the threshold value or to select a reference curve.

One development is that the electronic fuse is integrated into a power distributor.

One embodiment is that the power supply path is connected, at its other end, to a consumer of the on-board power supply system, for example to an electrically operated steering system, an electric brake, etc. The voltage measurement point is then advantageously located downstream of the associated connection system, such that it is also possible to take into consideration a degradation of this connection system (which is assigned to the power supply path).

One development is that the power supply path connects the on-board power supply system of the vehicle to an external power supply apparatus (for example a charging station, a socket of a domestic mains connection, etc., in particular for electric vehicles). The object is also achieved by a vehicle having such an on-board power supply system. The vehicle may be designed analogously to the on-board power supply system, and vice versa, and has the same advantages.

One embodiment is that the vehicle is a land vehicle, watercraft, aircraft or spacecraft. The land vehicle may be an automobile, a truck, a motorcycle, a bus, etc. The on-board power supply system is not restricted to any particular type of drive of the vehicle and may for example be used on vehicles with a motorized drive, hybrid drive or electric drive (for example based on a battery drive or hydrogen drive).

The object is also achieved by a method for identifying a degradation state of a power supply path of an on-board power supply system for a vehicle, in which a first voltage profile at a first end of the power supply path is recorded, at the same time, a second voltage profile at a second end of the power supply path is recorded, the first voltage profile and the second voltage profile are cross-correlated, and when the result of the cross-correlation meets a predefined criterion, an anomalous degradation state of the power supply path is identified.

The method may be designed analogously to the on-board power supply system and/or to the vehicle and has the same advantages.

The method may be performed “online” during operation of the vehicle. As an alternative or in addition, the method may be performed “offline” outside driving mode, for example in a workshop or garage. It is also possible to store the measured values or degrees of degradation and to read or evaluate them as back-end data.

It is also advantageous to use the method during production of the vehicle, for example in order to recognize faulty connection, plug connections and/or power lines.

The above-described properties, features and advantages of this invention and the way in which these are achieved will become clearer and more clearly comprehensible in connection with the following schematic description of one exemplary embodiment, which is explained in more detail in connection with the drawings.

### BRIEF DESCRIPTION OF THE DRAWINGS

FIG. 1 shows a simplified sketch of an on-board supply system of a vehicle.

FIG. 2 shows an excerpt of the sketch from FIG. 1.

FIG. 3 shows curve profiles of voltage measured values in a non-degraded state.

FIG. 4 shows curve profiles of voltage measured values in a degraded state.

### DETAILED DESCRIPTION OF THE DRAWINGS

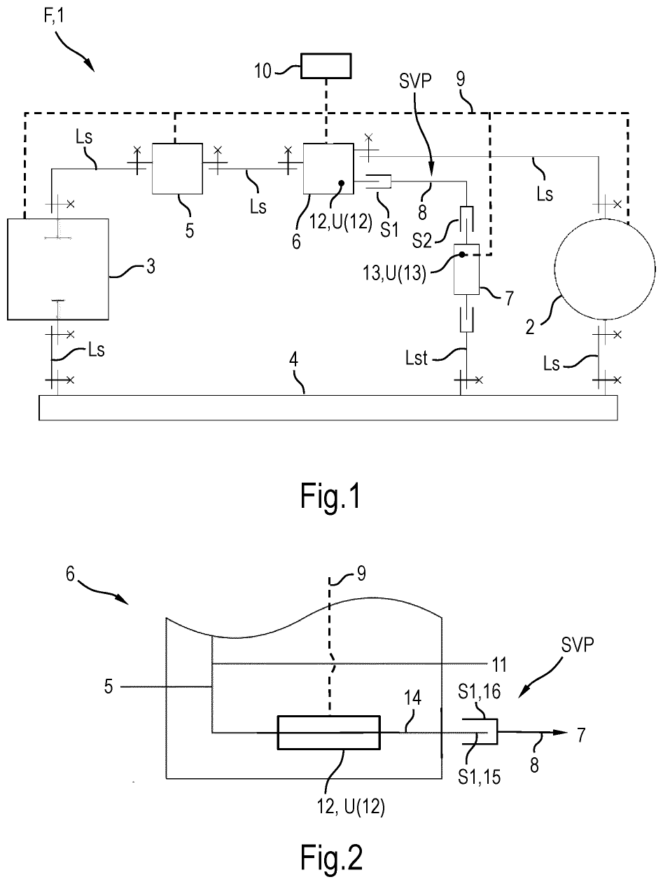

FIG. 1 shows a simplified sketch of an on-board supply system 1 of a vehicle F. The on-board supply system 1 has, purely by way of example, a generator 2 (for example an alternator) and a battery 3, whose negative poles are connected to a chassis 4, serving as reference potential, of the vehicle F by way of screwed power lines Ls.

A positive pole of the battery 4 is connected to a first power distributor 5 via a further screwed power line Ls, which first power distributor is connected to a second power distributor 6 via yet another screwed power line Ls. Further components of the on-board supply system 1 may be connected to the first power distributor 5 (top of figure). The second power distributor 6 is also connected to a positive pole of the generator 2 via yet another screwed power line Ls and plugged onto a consumer 7 via a cable 8. The consumer 7 is connected to the chassis 4 via a power line Lst.

In this case, there is, inter alia, a power supply path SVP between the second power distributor 6 and the consumer 7, which comprises the cable 8, a first electrical plug connection S1 of the cable 8 to the second power distributor 6 and a second electrical plug connection S2 of the cable 8 to the second power distributor 6.

The power supply path SVP, and thus the consumer 7, are protected via an electronic fuse 12 that is integrated into the second power distributor 6 and at which at least the voltage U(12) present at it and advantageously also the current flowing through it, and therefore also through the power supply path SVP, are able to be measured. A voltage-measuring device and advantageously also a current-measuring device are thus functionally integrated into the electronic fuse 12.

At the other end of the power supply path SVP, in or on the consumer 7, is a voltage-measuring device 13 at which a voltage U(13) is able to be measured and that, in one development, may likewise be designed as an electronic fuse. Other lines or branches of the second power distributor 6 may also be protected by respective electronic fuses (top of figure).

The voltage-measuring devices 12, 13, etc. are connected to data lines 9, via which voltages and/or currents measured thereby, or their measured values, are able to be transmitted to an evaluation apparatus, here for example in the form of an on-board computer 10.

FIG. 2 shows an excerpt of the second power distributor 6 of the on-board supply system 1. The electronic fuse 12 is connected, via a line path 14, to a plug connection element 15 of the first plug connection S1 and, via a plug connection mating element 16 plugged thereto of the first plug connection S1, to the cable 8. The plug connection element 15 may for example be integrated into a housing of the second power distributor.

The second power distributor 6 furthermore has an output to the first power distributor 5 and at least one further power supply output, as indicated here to a consumer 11.

Returning again to FIG. 1, the voltage or voltage difference ΔU on the power supply path SVP, including the line path 14, the plug connection S1, the cable 8, the plug connection S2 and possibly a line path from the plug connection S2 to the voltage-measuring device 13 (top of figure), may be calculated by calculating the difference between the voltage U(12) and the voltage U(13) according to ΔU=U(12)−U(13). In this case, the voltages U(12) and U(13) are advantageously measured simultaneously or synchronously.

In the same way as the power supply path SVP, voltages or voltage differences may in principle also be measured on any other power supply paths of the on-board power supply system 1. By way of example, the generator 2, the battery 3, the first power distributor 5 etc. may also be provided with respective voltage-measuring devices (top of figure), which are likewise connected to data lines 9, via which voltages and possibly currents measured at these components are able to be transferred to the on-board computer 10.

The on-board computer 10 is configured, for example programmed, to store the voltages U(12) and U(13) at least for the duration At of a predefined time window, which is possibly able to be adapted variably, in the form of voltage profiles or curves K[U(12)] and K[U(13)] and to cross-correlate them.

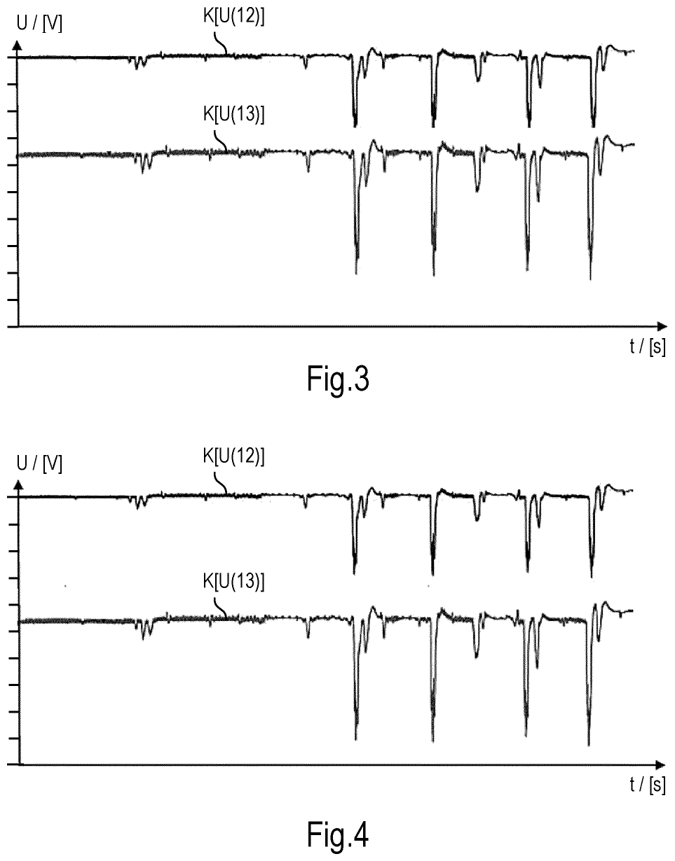

FIG. 3 shows exemplary voltage profiles K[U(12)] and K[U(13)] in a non-degraded state, in the form of a plot of voltage U against time. FIG. 4 shows, in a plot analogous to FIG. 3, the voltage profiles K[U(12)] and K[U(13)] in a degraded state with otherwise the same constraints or loading scenarios, for example with the same current strength, temperature, humidity, ageing, etc.

The result of the cross-correlation is a cross-correlation coefficient φ that is lower the more K[U(12)] and K[U(13)] deviate from one another. The cross-correlation coefficient φ may be calculated here for time windows containing M measurement points, for example in accordance with

$$φ = \frac{1}{M} \cdot {\sum }_{n = 0}^{M - 1} U ( 12 ) [ n ] \cdot U ( 13 ) [ n ]$$

Since the associated voltage-measuring apparatuses 12 and 13 constitute the endpoints of the common power supply path SVP, the shape thereof, for example comprising voltage peaks etc., is highly similar. Voltage peaks or voltage dips thus occur at the same time. Due to the ohmic resistance of the power supply path SVP, the voltage profile K[U(13)] is located lower down than the voltage profile K[U(12)]. This in turn means that the cross-correlation coefficient φ is a measure of the ohmic resistance of the power supply path SVP. The higher the resistance, the lower the value of the cross-correlation coefficient φ.

A degradation of the power supply path SVP is reflected in an increased ohmic resistance of the power supply path SVP. Accordingly, with the same shape and position of the voltage profile K[U(12)], the voltage profile K[U(13)] in FIG. 4 is located further down than the voltage profile K[U(13)] in FIG. 3. In other words, the distance between the voltage profiles K[U(12)] and K[U(13)] increases as degradation increases. The degradation of the power supply path SVP then leads to a decrease in the cross-correlation coefficient φ.

Now with reference again to FIG. 1, the on-board computer 10 is furthermore configured, for example programmed, to evaluate the cross-correlation coefficient φ and, when the cross-correlation coefficient φ meets a predefined criterion, to identify an anomalous degradation state of the power supply path SVP.

In one development that is particularly easy to implement, the on-board computer 10 may compare the value of the cross-correlation coefficient φ with a predefined threshold value. If the cross-correlation coefficient φ corresponds to the threshold value or is below the threshold value, an anomalous degradation state of the power supply path SVP is identified.

This may be expanded such that an anomalous degradation state of the power supply path is first identified when the cross-correlation coefficient φ reaches or falls below the threshold value multiple times within a predefined period.

The threshold value is advantageously a threshold value dependent on at least one ambient parameter such as temperature and/or humidity and/or a threshold value dependent on an operating age of the power supply path SVP, which yields the advantage that values of these parameters that may have a noticeable influence on the ohmic resistance of the power supply path SVP are taken into consideration in order to be able to distinguish changes of the cross-correlation coefficient φ that are brought about by these parameters from changes brought about by an anomalous degradation.

In one alternative or additional development, a temporal profile of the cross-correlation coefficient φ is evaluated. In one variant, it is possible to identify an anomalous degradation state of the power supply path when the profile exhibits a certain behavior, for example a comparatively rapid drop. In yet another variant, an anomalous degradation state of the power supply path may be identified when the profile of the cross-correlation coefficient φ deviates from a reference profile by more than a predefined measure, in particular moves away from the reference profile toward lower values. This deviation may for example be identified by the least squares method or via a further cross-correlation.

The reference profile that is used is advantageously a reference profile sought by the on-board computer 10 from a group or set of reference profiles. The reference profiles in this set may, in the same way as the threshold value, differ from one another based on the current temperature and/or humidity and/or based on an operating age of the power supply path SVP. The reference profiles may also differ in relation to a driving scenario, for example city driving or intercity driving. Generally speaking, a reference profile may represent a typical profile of the cross-correlation coefficient φ during a journey. The reference profile may for example have been defined through calculations, experiments, simulations and/or historical values. A reference profile may also be selected based on a location of the vehicle, wherein the location may for example be used to identify a climate zone in which the vehicle is located. This is particularly advantageous if, following use in a first climate zone, the vehicle is sold to a user in a second climate zone that has noticeably different daytime temperatures and/or humidities.

If an anomalous degradation state of the power supply path SVP is identified, a message or a notification may for example be output to the user of the vehicle and/or to at least one external entity such as for example to a workshop, the manufacturer of the vehicle, etc.

Of course, the present invention is not restricted to the exemplary embodiment shown above.

Generally speaking, “a”, “an”, “one” etc. may be understood to mean a single number or a multiplicity, in particular in the sense of “at least one” or “one or more”, provided that this is not explicitly ruled out, for example by the expression “exactly one”, etc.

A numerical specification may also comprise precisely the specified number and a conventional tolerance range, provided that this is not explicitly ruled out.

### LIST OF REFERENCE SIGNS

1 on-board supply system
2 generator
3 battery
4 chassis
5 first power distributor
6 second power distributor
7 consumer
8 cable
9 data line
10 on-board computer
11 consumer
12 electronic fuse
13 voltage-measuring device
14 line path
15 plug connection element
16 plug connection mating element
F vehicle
K[U(12)] temporal profile of the voltage U(12)
K[U(12)] temporal profile of the voltage U(13)
Ls screwed power line
Lst power line
SVP power supply path
S1 first plug connection
S2 second plug connection
U(12) voltage at the electronic fuse
U(13) voltage at the voltage-measuring device

1.-10. (canceled)

11. An on-board power supply system for a vehicle, the on-board power supply system comprising:
an electric power supply path,
a first voltage-measuring device at a first end of the power supply path,
a second voltage-measuring device at a second end of the power supply path, and
an evaluation apparatus that is connected to the first voltage-measuring device and the second voltage-measuring device,
wherein the evaluation apparatus is configured to cross-correlate a first voltage profile measured by way of the first voltage-measuring device and a second voltage profile measured by way of the second voltage-measuring device and, when a result of a cross-correlation meets a predefined criterion, to identify an anomalous degradation state of the power supply path.

12. The on-board power supply system according to claim 11, wherein the criterion is a cross-correlation coefficient reaching or falling below a predefined threshold value.

13. The on-board power supply system according to claim 12, wherein the threshold value is variably adaptable to at least one ambient parameter and/or to ageing of the power supply path.

14. The on-board power supply system according to claim 11, wherein the criterion comprises a deviation of a profile of a cross-correlation coefficient from a reference profile.

15. The on-board power supply system according to claim 14, wherein the reference profile comprises a profile of cross-correlation coefficients that is typical for a journey of the vehicle.

16. The on-board power supply system according to claim 11, wherein the first voltage profile and the second voltage profile are determined in a concomitant time window.

17. The on-board power supply system according to claim 11, wherein the power supply path comprises at least one electrical connection system.

18. The on-board power supply system according to claim 11, wherein the power supply path comprises a plug connection.

19. The on-board power supply system according to claim 11, wherein the first end of the power supply path and/or the second end of the power supply path has an electronic fuse into which the first voltage-measuring device or the second voltage-measuring device is integrated.

20. A vehicle comprising the on-board power supply system according to claim 11.

21. A method for identifying a degradation state of a power supply path of an on-board power supply system for a vehicle, the method comprising:
recording a first voltage profile at a first end of the power supply path,
simultaneously recording a second voltage profile at a second end of the power supply path,
cross-correlating the first voltage profile and the second voltage profile, and
when a result of a cross-correlation meets a predefined criterion, identifying an anomalous degradation state of the power supply path.
